(19) United States
(12) Patent Application Publication
(10) Pub. No.: US 2022/0076927 A1
(43) Pub. Date: Mar. 10, 2022

(54) PART WITH CORROSION-RESISTANT LAYER

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Ki Yong PARK, Gyeonggi-do (KR)

(73) Assignee: POINT ENGINEERING CO., LTD., Chungcheongnam-do (KR)

(21) Appl. No.: 17/465,856

(22) Filed: Sep. 3, 2021

(30) Foreign Application Priority Data
Sep. 9, 2020 (KR) 10-2020-0115674

(51) Int. Cl. H01J 37/32; C23C 4/11

(52) U.S. Cl. CPC H01J 37/32495; H01L 21/68757; C23C 4/11

(57) ABSTRACT

Proposed is a part with a corrosion-resistant layer capable of preventing the exposure of pores attributable to corrosion and preventing the discharge of internal moisture and particles through the pores.

### CROSS REFERENCE TO RELATED APPLICATION

The present application claims priority to Korean Patent Application No. 10-2020-0115674, filed on Sep. 9, 2020, the entire contents of which is incorporated herein for all purposes by this reference.

### BACKGROUND OF THE INVENTION

### Field of the Invention

The present invention relates generally to a part with a corrosion-resistant layer and, more particularly, to a part with a corrosion-resistant layer, the part being installed in a process chamber used in a semiconductor manufacturing process.

### Description of the Related Art

In recent years, high productivity and high quality have been demanded in a deposition process used to manufacture semiconductor devices.

In meet this demand, efforts have been made to increase the process speed in a deposition process by increasing the RF power output of a plasma source, and to shorten the production time by using NF₃ corrosive gas under high temperature conditions in a plasma cleaning process.

During the plasma cleaning process, deposition equipment is under exposure to a high-temperature plasma gas atmosphere including fluorine. The deposition equipment includes a support for fixing a wafer in a process chamber. The support is also under exposure to a high-temperature plasma gas atmosphere during the plasma cleaning process. The support may include a ceramic heater used for semiconductor processing and made of a porous ceramic material, and an electrostatic chuck.

When the ceramic heater is exposed to high-temperature plasma gas, the ceramic material of the ceramic heater reacts with fluorine radicals and ions and thus forms an aluminum fluoride reaction layer on the surface thereof. The aluminum fluoride reaction layer starts to vaporize at a high temperature (e.g., 450° C.), and the vaporization reaction is continuously carried out as the deposition or cleaning process is repeated. The vaporization of the aluminum fluoride reaction layer may cause a problem of increasing the corroded area of the ceramic heater.

The surface layer of the ceramic heater gradually becomes thinner as it is corroded, resulting in strength reduction and cracking. In addition, substances vaporized from the aluminum fluoride reaction layer are deposited and attached to an internal wall surface of the chamber because the internal wall surface has a relatively low temperature in the chamber. This deposit acts as a significant source of contamination in the form of particles.

Particles generated from the aluminum fluoride reaction layer may adhere to the wafer, thereby contaminating the wafer and causing defects on the wafer. The particles also cause a problem of lowering the production yield of semiconductor devices.

As a solution to the problems of corrosion and particle generation, a method of modifying the surface of a ceramic heater exposed to plasma gas may be considered.

Examples of such a surface modification technique include a method of forming a thin film layer on the surface through ceramic thermal spraying or chemical vapor deposition (CVD).

FIG. 1 is a view illustrating a porous ceramic body PC as viewed from above, and FIG. 2 is an enlarged view illustrating a portion of the porous ceramic body PC having the surface that is treated through chemical vapor deposition.

As an example, a ceramic heater for semiconductors may be formed from the porous ceramic body PC illustrated in FIG. 1. The porous ceramic body PC may have a plurality of pores S formed between a plurality of grains G. As illustrated in FIG. 2, a thin film layer P may be formed on the surface of the porous ceramic body PC using chemical vapor deposition.

The thin film layer P is formed through chemical vapor deposition to cover the surfaces of the grains S along the surface of the porous ceramic body PC, thereby blocking the top of each of the pores S formed in the vicinity of the grains G. That is, the thin film layer P covers the tops of the respective pores S. In this case, when the porous ceramic body PC is viewed from above, the pores S are blocked by the thin film layer P. However, since the thin film layer P covers only the tops of the pores S, the inside spaces of the pores S may still exist in the form of voids.

However, such a structure is problematic in that the thin film layer P becomes thinner or cracked as it is corroded, thereby causing the pores S to be uncovered by the thin film layer P and to be exposed to outside. The exposed pores S undesirably act as passages through which internal moisture and foreign substances existing inside the porous ceramic body PC are discharged to the outside. This may lead to contamination of the wafer, resulting in problems of process defects in a process chamber and a reduction in production yield.

As an alternative method of modifying the surface of the porous ceramic body PC, thermal spraying and aerosol coating techniques may be employed. However, a thin film layer formed through such thermal spraying and aerosol coating techniques has limitations in terms of prevention of corrosion. One possible approach to improve the corrosion prevention effect lies in increasing the thickness of the thin film layer. However, this approach is limited in that the thermal properties (thermal conductivity or heat capacity) of the porous ceramic may be affected by the increased thickness of the thin film layer, and fractures and cracks may occur due to the difference in coefficient of thermal expansion between the thick thin film layer and the porous ceramic material.

The foregoing is intended merely to aid in the understanding of the background of the present invention, and is not intended to mean that the present invention falls within the purview of the related art that is already known to those skilled in the art.

### DOCUMENTS OF RELATED ART

(Patent document 1) Korean Patent Application Publication No. 10-2005-0053629

### SUMMARY OF THE INVENTION

Accordingly, the present invention has been made keeping in mind the above problems occurring in the related art, and an objective of the present invention is to provide a part with a corrosion-resistant layer. The corrosion-resistant layer fills pores to prevent the exposure of the pores attributable to corrosion and prevent the discharge of internal moisture and particles through the pores.

In order to achieve the above objective, according to one aspect of the present invention, there is provided a part with a corrosion-resistant layer, the part including: a porous ceramic body with a plurality of pores; and the corrosion-resistant layer formed on a surface of the porous ceramic body. The corrosion-resistant layer may be formed to fill the pores of the porous ceramic body, thereby sealing the pores.

The porous ceramic body may include at least one of alumina (Al₂O₃), aluminum nitride (AlN), silicon carbide (SiC), yttria (Y₂O₃), boron nitride (BN), zirconia (ZrO₂), and silicon nitride (Si₃N₄).

The corrosion-resistant layer may include at least one of an aluminum oxide layer, an yttrium oxide layer, a hafnium oxide layer, a silicon oxide layer, an erbium oxide layer, a zirconium oxide layer, a fluoride layer, a transition metal layer, a titanium nitride layer, a tantalum nitride layer, and a zirconium nitride layer.

The corrosion-resistant layer may include: a surface corrosion-resistant layer formed on the surface of the porous ceramic; and a pore corrosion-resistant layer formed inside the pores of the porous ceramic body. The length of the pore corrosion-resistant layer in the depth direction of the porous ceramic body may be larger than the thickness of the surface corrosion-resistant layer in at least a partial area.

The pores may include macropores, mesopores, and nanopores that have different pore sizes, respectively, and the corrosion-resistant layer may seal the pores by filling the nanopores.

The pores may include macropores, mesopores, and nanopores that have different pore sizes, respectively, and the corrosion-resistant layer may seal the pores by filling the mesopores.

The corrosion-resistant layer may be formed by alternately feeding a precursor gas, which is at least one of aluminum, silicon, hafnium, zirconium, yttrium, erbium, titanium, and tantalum, and a reactant gas capable of forming the corrosion-resistant layer.

According to another aspect of the present invention, there is provided a part with a corrosion-resistant layer, the part including: a body; a porous ceramic layer formed on the body and provided with a plurality of pores; and the corrosion-resistant layer formed on a surface of the porous ceramic layer, wherein the corrosion-resistant layer fills the pores of the porous ceramic layer, thereby sealing the pores.

The porous ceramic layer may be formed by thermal spraying of a thermal spray material.

The porous ceramic layer may include at least one of alumina (Al₂O₃), aluminum nitride (AlN), silicon carbide (SiC), yttria (Y₂O₃), boron nitride (BN), zirconia (ZrO₂), and silicon nitride (Si₃N₄).

The corrosion-resistant layer may include: a surface corrosion-resistant layer formed on the surface of the porous ceramic layer; and a pore corrosion-resistant layer formed inside the pores of the porous ceramic layer. The length of the pore corrosion-resistant layer in the depth direction of the porous ceramic layer may be larger than the thickness of the surface corrosion-resistant layer in at least a partial area.

The pores may include macropores, mesopores, and nanopores that have different pore sizes, respectively, and the corrosion-resistant layer may seal the pores by filling the nanopores.

The pores may include macropores, mesopores, and nanopores that have different pore sizes, respectively, and the corrosion-resistant layer may seal the pores by filling the mesopores.

The corrosion-resistant layer may be formed by alternately feeding a precursor gas, which is at least one of aluminum, silicon, hafnium, zirconium, yttrium, erbium, titanium, and tantalum, and a reactant gas capable of forming the corrosion-resistant layer.

The part with the corrosion-resistant layer according to the present invention is featured in that the possibility of exposure of the pores is prevented even if the corrosion-resistant layer provided on the surface of the part is corroded and becomes thinner. Therefore, it is possible to prevent internal moisture and foreign substances from being discharged through the pores. This enables the prevention of wafer contamination and defects, thereby improving the production yield of semiconductor devices.

### BRIEF DESCRIPTION OF THE DRAWINGS

The above and other objectives, features, and other advantages of the present invention will be more clearly understood from the following detailed description when taken in conjunction with the accompanying drawings, in which:

FIG. 1 is a view illustrating a porous ceramic as viewed from above;

FIG. 2 is an enlarged view illustrating a portion of the porous ceramic having the surface treated through chemical vapor deposition;

FIG. 3A is an enlarged view illustrating a monoatomic layer constituting a corrosion-resistant layer of a part with the corrosion-resistant layer according to a first embodiment of the present invention;

FIG. 3B is an enlarged view illustrating a portion of a surface of the part with the corrosion-resistant layer according to the first embodiment of the present invention;

FIG. 4 is a view illustrating a process of manufacturing the part with the corrosion-resistant layer according to the first embodiment of the present invention;

FIG. 5 is a view illustrating a process of manufacturing a modified example of a part with a corrosion-resistant layer according to a second embodiment of the present invention; and

FIG. 6 is a schematic view illustrating a process chamber for a chemical vapor deposition process, the process chamber including the part with the corrosion-resistant layer according to the present invention.

### DETAILED DESCRIPTION OF THE INVENTION

Contents of the description below merely exemplify the principle of the present disclosure. Therefore, those of ordinary skill in the art may implement the theory of the present disclosure and invent various apparatuses which are included within the concept and the scope of the invention even though it is not clearly explained or illustrated in the description. Furthermore, in principle, all the conditional terms and embodiments listed in this description are clearly intended for the purpose of understanding the concept of the present disclosure, and one should understand that this invention is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present invention. For explicit and convenient description of the technical content, thicknesses and widths of regions in the figures may be exaggerated. Therefore, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing.

Hereinafter, exemplary embodiments of the present invention will be described in detail with reference to the accompanying drawings.

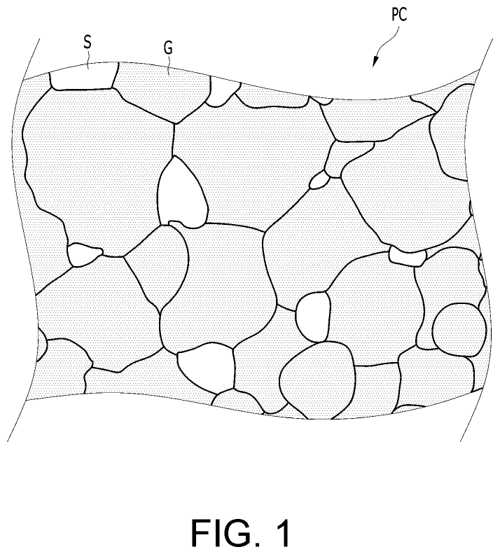

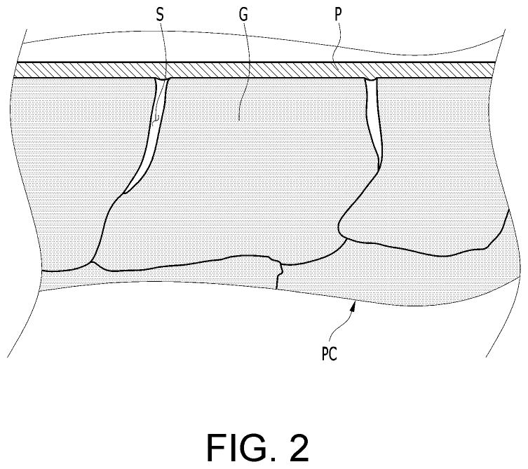

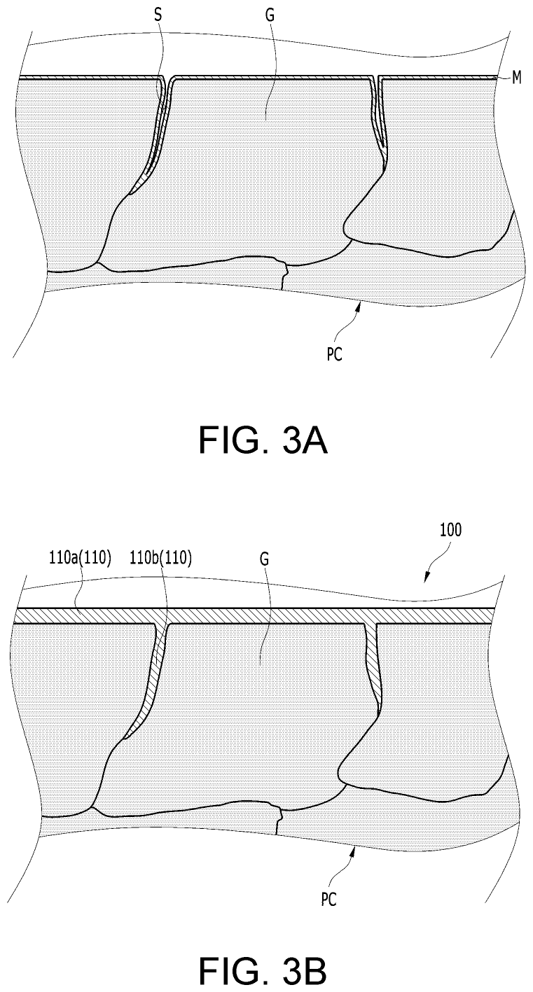

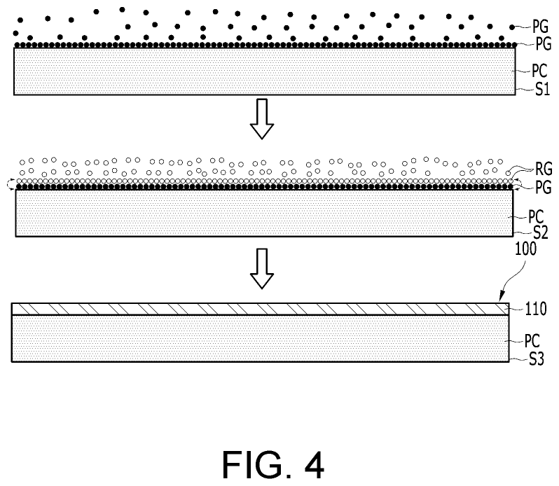

FIG. 1 is a view illustrating a porous ceramic body PC as viewed from above, FIG. 2 is an enlarged view illustrating a portion of the porous ceramic body PC having the surface treated through chemical vapor deposition, FIG. 3A is an enlarged view illustrating a monoatomic layer M constituting a corrosion-resistant layer 110 of a part 100 with the corrosion-resistant layer 110 according to a first embodiment of the present invention, FIG. 3B is an enlarged view illustrating a portion of a surface of the part 100 with the corrosion-resistant layer 110 according to the first embodiment of the present invention, and FIG. 4 is a view illustrating a process of manufacturing the part 100 with the corrosion-resistant layer 110 according to the first embodiment of the present invention.

The part 100 with the corrosion-resistant layer 110 according to the first embodiment of the present invention may be, for example, at least one part which is provided in a chamber of equipment for performing a deposition process, or constitutes a wall surface of the chamber, or allows gas to flow into and out of the chamber. As a specific example, the part 100 with the corrosion-resistant layer 110 according to the first embodiment of the present invention may be a ceramic heater for semiconductors that supports a wafer in a process chamber and transfer heat to the wafer seated thereon, or may be an electrostatic chuck that minimizes the generation of static electricity.

Hereinafter, the part 100 with the corrosion-resistant layer 110 according to the first embodiment of the present invention will be described as being provided as a ceramic heater for semiconductors in a chamber of process equipment.

As illustrated in FIG. 3B, the part 100 with the corrosion-resistant layer 110 according to the first embodiment of the present invention may include the porous ceramic body PC and the corrosion-resistant layer 110 formed on a surface of the porous ceramic body PC.

The porous ceramic body PC may be fabricated by: preparing a composition containing a powder of at least one of alumina (Al₂O₃), aluminum nitride (AlN), silicon carbide (SiC), yttria (Y₂O₃), boron nitride (BN), zirconia (ZrO₂), and silicon nitride (Si₃N₄), a binder, and a remainder; molding the composition within a mold to obtain a molded body; and sintering the molded body, followed by planarizing a surface of the molded body.

Therefore, the porous ceramic body PC may include at least one of alumina (Al₂O₃), aluminum nitride (AlN), silicon carbide (SiC), yttria (Y₂O₃), boron nitride (BN), zirconia (ZrO₂), and silicon nitride (Si₃N₄).

Since the porous ceramic body PC is fabricated by the ceramic sintering technique, it may have a structure in which a plurality of disordered pores S are formed between a plurality of grains G.

The pores S of the porous ceramic body PC may include macropores S, mesopores S, and nanopores S that have different pore sizes, respectively.

The macropores S may have a pore size in a range of from several hundred nm to several μm. The macropores S preferably have a pore size in a range of from 100 nm to 1 μm.

The mesopores S may have a pore size in a range of from several nm to several tens of nm. The mesopores S preferably have a pore size in a range of 5 nm to 50 nm.

The nanopores S may have a pore size in a range of from several nm to several nm. The nanopores S preferably have a pore size in a range of from 1 nm to 4 nm.

The corrosion-resistant layer 110 may be formed on the surface of the porous ceramic body PC.

The corrosion-resistant layer 110 may be formed to fill the pores S of the porous ceramic body PC, thereby sealing the pores S. The corrosion-resistant layer 110 may fill the inside spaces of the pores S, thereby completely seals the pores S. The corrosion-resistant layer 110 may fully fill the inside spaces of the pores S, thereby completely sealing the tops of the pores S so that no voids exist inside the pores S. Since the corrosion-resistant layer 110 seals the pores S by filling the inside spaces of the pores S rather than covering only the tops of the pores S, this may realize a structure in which no pores S exist between the grains G.

The part 100 with the corrosion-resistant layer 110 according to the first embodiment of the present invention may have a structure in which the corrosion-resistant layer 110 exists between the surface of the porous ceramic body PC and the grains G. With this structure of the part 100 with the corrosion-resistant layer 110 according to the first embodiment of the present invention, there may exist no pores S undesirably acting as passages through which internal moisture and foreign substances existing inside the porous ceramic body PC are discharged to the outside. Therefore, unlike the related art, the moisture and foreign substances may be prevented from being discharged through the pores S.

The corrosion-resistant layer 110 may have corrosion resistance to a process gas including a reactant gas, an etching gas, or a cleaning gas used during the deposition process.

The corrosion-resistant layer 110 may be formed by alternately feeding a precursor gas PG and a reactant gas RG. In this case, the corrosion-resistant layer 110 may be embodied as a variety of different types of corrosion-resistant layers depending on the constituent components of the precursor gas PG and the reactant gas RG.

As an example, the corrosion-resistant layer 110 may be formed by alternately feeding the precursor gas PG, which is at least one of aluminum, silicon, hafnium, zirconium, yttrium, erbium, titanium, and tantalum, and the reactant gas capable of forming the corrosion-resistant layer 110.

Depending on the constituent components of the precursor gas PG and the reactant gas RG, the corrosion-resistant layer 110 formed by alternately feeding the precursor gas PG and the reactant gas may include at least one of an aluminum oxide layer, an yttrium oxide layer, a hafnium oxide layer, a silicon oxide layer, an erbium oxide layer, a zirconium oxide layer, a fluoride layer, a transition metal layer, a titanium nitride layer, a tantalum nitride layer, and a zirconium nitride layer.

Specifically, when the corrosion-resistant layer 110 is an aluminum oxide layer, the precursor gas PG may include at least one of aluminum alkoxide (Al(T-OC₄H₉)₃), aluminum chloride (AlCl₃), trimethyl aluminum (TMA: Al(CH₃)₃), diethylaluminum ethoxide, tris(ethylmethylamido)aluminum, aluminum sec-butoxide, aluminum tribromide, aluminum trichloride, triethylaluminum, triisobutylaluminum, trimethylaluminum, and tris(diethylamido)aluminum.

In this case, when at least one of aluminum alkoxide (Al(T-OC₄H₉)₃), diethylaluminum ethoxide, tris(ethylmethylamido)aluminum, aluminum sec-butoxide, aluminum tribromide, aluminum trichloride, triethylaluminum, triisobutylaluminum, trimethylaluminum, and tris(diethylamido)aluminum is used as the precursor gas PG, H₂O may be used as the reactant gas RG.

When aluminum chloride (AlCl₃) is used as the precursor gas PG, O₃ may be used as the reactant gas RG.

When trimethyl aluminum (TMA: Al(CH₃)₃) is used as the precursor gas PG, O₃ or H₂O may be used as the reactant gas RG.

When the corrosion-resistant layer 110 is a yttrium oxide layer, the precursor gas PG may include at least one of yttrium chloride (YCl₃), Y(C₅H₅)₃, tris(N,N-bis(trimethylsilyl)amide)yttrium(III), yttrium(III)butoxide, tris(cyclopentadienyl)yttrium(III), tris(butylcyclopentadienyl)yttrium(III), tris(2,2,6,6-tetramethyl-3,5-heptanedionato)yttrium(III), tris(cyclopentadienyl)yttrium (Cp₃Y), tris(methylcyclopentadienyl)yttrium ((CpMe)3Y), tris(butylcyclopentadienyl)yttrium, and tris(ethylcyclopentadienyl)yttrium.

In this case, when at least one of yttrium chloride (YCl₃) and Y(C₅H₅)₃ is used as the precursor gas PG, O₃ may be used as the reactant gas RG.

When at least one of tris(N,N-bis(trimethylsilyl)amide)yttrium(III), yttrium(III)butoxide, tris(cyclopentadienyl)yttrium(III), tris(butylcyclopentadienyl)yttrium(III), tris(2,2,6,6-tetramethyl-3,5-heptanedionato)yttrium(III), tris(cyclopentadienyl)yttrium (Cp3Y), tris(methylcyclopentadienyl)yttrium ((CpMe)3Y), tris(butylcyclopentadienyl)yttrium, and tris(ethylcyclopentadienyl)yttrium is used as the precursor gas PG, at least one of H₂0, O₂, and O₃ may be used as the reactant gas RG.

When the corrosion-resistant layer 110 is a hafnium oxide layer, the precursor gas PG may include at least one of hafnium chloride (HfCl₄), Hf (N(CH₃) (C₂H₅)₂)₄, Hf(N(C₂H₅)₂)₄, tetrakis(ethylmethylamido)hafnium, and pentakis(dimethylamido)tantalum.

In this case, when at least one of hafnium chloride (HfCl₄), Hf(N(CH₃) (C₂H₅))₄, and Hf(N(C₂H₅)₂)₄ is used as the precursor gas PG, O₃ may be used as the reactant gas RG.

When at least one of tetrakis(ethylmethylamido)hafnium and pentakis(dimethylamido)tantalum is used as the precursor gas PG, at least one of H₂O, O₂, and O₃ may be used as the reactant gas RG.

When the corrosion-resistant layer 110 is a silicon oxide layer, the precursor gas PG may include Si(OC₂H₅)₄. In this case, O₃ may be used as the reactant gas RG.

When the corrosion-resistant layer 110 is an erbium oxide layer, the precursor gas PG may include at least one of tris-methylcyclopentadienyl erbium(III) (Er(MeCp)₃), erbium boranamide (Er(BA)₃), Er(TMHD)₃, erbium(III)tris(2,2,6,6-tetramethyl-3,5-heptanedionate), tris(butylcyclopentadienyl)erbium(III), tris(2,2,6,6-tetramethyl-3,5-heptanedionato)erbium (Er(thd)₃), Er(PrCp)₃, Er(CpMe)₂, Er(BuCp)₃, and Er(thd)₃.

In this case, when at least one of tris-methylcyclopentadienyl erbium(III) (Er(MeCp)₃), erbium boranamide (Er(BA)₃), Er(TMHD)₃, erbium(III)tris(2,2,6,6-tetramethyl-3,5-heptanedionate), and tris(butylcyclopentadienyl)erbium(III) is used as the precursor gas PG, at least one of H₂O, O₂, and O₃ may be used as the reactant gas RG.

When at least one of tris(2,2,6,6-tetramethyl-3,5-heptanedionato)erbium (Er(thd)₃), Er(PrCp)₃, Er(CpMe)₂, and Er(BuCp)₃ is used the precursor gas PG, O₃ may be used as the reactant gas RG.

When Er(thd)₃ is used as the precursor gas PG, an O radical may be used as the reactant gas RG.

When the corrosion-resistant layer 110 is a zirconium oxide, the precursor gas PG may include at least one of zirconium tetrachloride (ZrCl₄) , Zr(T-OC₄H₉)₄ zirconium(IV) bromide, tetrakis(diethylamido)zirconium(IV), tetrakis(dimethylamido)zirconium(IV), tetrakis(ethylmethylamido)zirconium(IV), tetrakis(N,N′-dimethyl-formamidinate)zirconium, tetrakis(ethylmethylamido)hafnium, pentakis(dimethylamido)tantalum, tris(dimethylamino)(cyclopentadienyl)zirconium, and tris(2,2,6,6-tetramethyl-heptane-3,5-dionate)erbium.

When at least one of these components is used as the precursor gas PG, at least one of H₂O, O₂, O₃, and an O radical may be used as the reactant gas RG.

When the corrosion-resistant layer 110 is a fluorinated layer, the precursor gas PG may include tris(2,2,6,6-tetramethyl-3,5-heptanedionato)yttrium(III). In this case, at least one of H₂O, O₂, and O₃ may be used as the reactant gas RG.

When the corrosion-resistant layer 110 is a transition metal layer, the precursor gas PG may include at least one of tantalum pentachloride (TaCl₅) and titanium tetrachloride (TiCl₅. In this case, an H radical may be used as the reactant gas RG.

Specifically, when tantalum pentachloride (TaCl₅) is used as the precursor gas PG and the H radical is used as the reactant gas RG, the transition metal layer may be a tantalum layer.

On the other hand, when titanium tetrachloride (TiCl₄) is used as the precursor gas PG and the H radical is used as the reactant gas RG, the transition metal layer may be a titanium layer.

When the corrosion-resistant layer 110 is a titanium nitride layer, the precursor gas PG may include at least one of bis(diethylamido)bis(dimethylamido)titanium(IV), tetrakis(diethylamido)titanium(IV), tetrakis(dimethylamido)titanium(IV), tetrakis(ethylmethylamido)titanium(IV), titanium(IV) bromide, titanium(IV) chloride, and titanium(IV) tert-butoxide. In this case, at least one of H₂O, O₂, O₃, and an O radical may be used as the reactant gas RG.

When the corrosion-resistant layer 110 is a tantalum nitride layer, the precursor gas PG may include at least one of pentakis(dimethylamido)tantalum(V), tantalum(V) chloride, tantalum(V) ethoxide, and tris(diethylamino)(tert-butylimido)tantalum(V). In this case, at least one of H₂O, O₂, O₃, and an O radical may be used as the reactant gas RG.

When the corrosion-resistant layer 110 is a zirconium nitride layer, the precursor gas PG may include at least one of zirconium(IV) bromide, zirconium(IV) chloride, zirconium(IV) tert-butoxide, tetrakis(diethylamido)zirconium(IV), tetrakis(dimethylamido)zirconium(IV), and tetrakis(ethylmethylamido)zirconium(IV). In this case, at least one of H₂O, O₂, O₃, and an O radical may be used as the reactant gas RG.

As described above, the corrosion-resistant layer 110 may be embodied as a variety of different types of corrosion-resistant layers depending on the constituent components of the precursor gas PG and the reactant gas RG used.

As illustrated in FIG. 4, the corrosion-resistant layer 110 may be formed by repeating a cycle (hereinafter referred to as a “monatomic layer generation cycle”) in which the precursor gas PG is adsorbed on the surface of the porous ceramic body PC, and the reactant gas RG is fed to generate the monoatomic layer M through chemical substitution of the precursor gas PG with the reactant gas RG.

As illustrated in FIG. 3A, when one cycle of generating the monoatomic layer M is performed, one thin monoatomic layer M may be formed in the pores S. As the cycle of generating the monoatomic layer M is repeated, a plurality of monoatomic layers M may be formed in the pores S. The plurality of monoatomic layers M may fill the pores S in a laminated manner, resulting in the corrosion-resistant layer 110 filling the pores S.

In other words, as each monoatomic layer M is deposited sequentially on inner surfaces of the pores S of the porous ceramic body PC depending on the number of times, the monoatomic layer generation cycle is performed, the plurality of monoatomic layers M may fully fill the pores S, thereby forming the corrosion-resistant layer 110.

More specifically, the part 100 with the corrosion-resistant layer 110 according to the first embodiment of the present invention may be manufactured by the following steps of: a preparation step (not illustrated) of providing the porous ceramic body PC; and a corrosion-resistant layer forming step (S3) of forming the corrosion-resistant layer 110 by generating the plurality of monoatomic layers M by repeating the monoatomic layer generation cycle including a precursor gas adsorption step (S1) of adsorbing the precursor gas PG on the surface of the porous ceramic body PC, an inert gas feeding step (not illustrated), a reactant gas adsorption and substitution step (S2), and an inert gas feeding step (not illustrated).

The precursor gas adsorption step (S1) may be performed by forming a precursor adsorption layer by feeding and adsorbing the precursor gas PG on the surface of the porous ceramic body PC. One precursor adsorption layer is formed through a self-limiting reaction.

Then, the inert gas feeding step may be performed. The inert gas feeding step may be performed by removing excess precursor from the precursor adsorption layer by feeding the inert gas. The inert gas removes excess precursor remaining in the one precursor adsorption layer formed through the self-limiting reaction.

Then, the reactant gas adsorption and substitution step (S2) may be performed. The double-headed arrow illustrated in step S2 of FIG. 4 denotes the substitution of the precursor gas PG with the reactant gas RG.

The reactant gas adsorption and substitution step (S2) may be performed by adsorbing the reactant gas RG on a surface of the precursor adsorption layer by feeding the reactant gas RG on the surface of the precursor adsorption layer, and forming the monoatomic layer M through chemical substitution of the precursor adsorption layer with the reactant gas RG.

Then, the inert gas feeding step may be performed by removing excess reactant gas RG by feeding the inert gas.

Finally, the corrosion-resistant layer forming step (S3) may be performed. The corrosion-resistant layer forming step (S3) may be performed by generating the plurality of monoatomic layers M by repeating the monoatomic layer generation cycle, thereby forming the corrosion-resistant layer 110.

As illustrated in FIGS. 3A and 3B, the corrosion-resistant layer 110 may be formed in the pores S existing between the surface of the porous ceramic body PC and the grains G by repeating the monoatomic layer generation cycle. Therefore, the corrosion-resistant layer 110 may include a surface corrosion-resistant layer 110a formed on the surface of the porous ceramic body PC and a pore corrosion-resistant layer 110b formed inside the pores S of the porous ceramic body PC.

The surface corrosion-resistant layer 110a may be formed on the surfaces of grains G existing near the surface of the porous ceramic body PC to minimize surface corrosion of the porous ceramic body PC.

The pore corrosion-resistant layer 110b may be formed by depositing the monoatomic layers M on the entire inner surfaces of the pores S by means of the precursor gas PG and the reactant gas RG that penetrate into the gaps, i.e., the pores S, existing between the grains G of the porous ceramic body PC, and are adsorbed therein during the monoatomic layer generation cycle. The pore corrosion-resistant layer 110b may be in a form in which the plurality of monoatomic layers M are laminated in the pores S to fully fill the pores S as the monoatomic layer generation cycle is repeated.

The part 100 with the corrosion-resistant layer 110 according to the first embodiment of the present invention may have a structure in which the pore corrosion-resistant layer 110b fills the pores S, and the surface corrosion-resistant layer 110a is formed on the tops of the pores S, so that the corrosion-resistant layer 110 completely seals the pores S. With this structure, particles that may act as a source of contamination and defects on a wafer W may be prevented from being discharged through the pores S.

The length of the pore corrosion-resistant layer 110b in the depth direction of the porous ceramic body PC may be larger than the thickness of the surface corrosion-resistant layer 110a in at least a partial area. Since the pore corrosion-resistant layer 110b is fully formed in the pores S by repeating the monoatomic layer generation cycle, when the length of pores S existing near the surface of the porous ceramic body PC in the depth direction thereof is relatively long, the pore corrosion-resistant layer 110b may have a length larger than the thickness of the surface corrosion-resistant layer 110a in at least a partial area of the part 100 with the corrosion-resistant layer 110. As an example, as illustrated in FIGS. 3A and 3B, the pore corrosion-resistant layer 110b may be formed in the pores S having a relatively long length in the depth direction of the porous ceramic body PC, thereby having a length larger than the thickness of the surface corrosion-resistant layer 110a.

By configuring the length of the pore corrosion-resistant layer 110b to be larger than the thickness of the surface corrosion-resistant layer 110a, the part 100 with the corrosion-resistant layer 110 may have a structure in which the pores S are not exposed even if the surface corrosion-resistant layer 110a is corroded under exposure to process gases after long-term use.

In addition, in the case of the part 100 with the corrosion-resistant layer 110 according to the first embodiment of the present invention, the corrosion-resistant layer 110 may be formed on the entire surface of the porous ceramic body PC including the surfaces of the grains G existing near the surface of the porous ceramic body PC while filling the inside spaces of the pores S existing near the surface of the porous ceramic body PC between the grains G. Therefore, the part 100 with the corrosion-resistant layer 110 according to the first embodiment of the present invention may have a structure in which no voids exist between the grains G and the pores S existing near the surface of the porous ceramic body PC.

Unlike the monoatomic layer generation cycle of generating the corrosion-resistant layer 110 of the part 100 provided with the corrosion-resistant layer 110 according to the first embodiment of the present invention, as illustrated in FIG. 2, when a thin film layer P is formed by conventional chemical vapor deposition, the thin film layer P may be formed to cover and block the tops of pores S.

In this case, the inside spaces of the pores S still exist in the form of voids.

Referring to FIG. 2, the sizes of the pores S existing in a porous ceramic body PC may vary along the depth direction of the porous ceramic body PC. Each of the pores S may include a macropore S, a mesopore S, and a nanopore S that have different pore sizes, respectively. As an example, as illustrated in FIG. 2, each of the pores S may be configured such that the macropore S, the mesopores S, and the nanopores S are in communication with each other in the depth direction of the porous ceramic body PC.

As an example, as illustrated in FIG. 2, when a section having the largest width corresponds to the macropore S, a pore S existing near the surface of the porous ceramic body PC may be the macropore S. In the case of using conventional chemical vapor deposition techniques, the thin film layer P may be formed to block at least a portion of each macropore S, but may not fill the macropore S and not flow down to be disposed in the mesopore S or the nanopore S formed under the macropore S.

When the pore S existing near the surface of the porous ceramic body PC is at least one of the mesopore S and the nanopore S having a width smaller than that of the macropore S, the thin film layer P according to the related art may be formed to cover and block the top of the pore S, but may not be formed in the remaining pores S formed in the depth direction of the porous ceramic body PC. Therefore, when the thin film layer P is formed by conventional chemical vapor deposition, the remaining pores S formed in the depth direction under the pore S existing near the surface of the porous ceramic body PC may exist in the form of voids.

Since the thin film layer P of the porous ceramic body PC is formed to cover the tops of the pores S, the thin film layer P may become thinner or cracked as it is corroded when exposed to process gases after long-term use. As a result, the inside spaces of the pores S of the porous ceramic body PC may be uncovered by the thin film layer P and exposed to the outside. Internal moisture and foreign substances existing inside the porous ceramic body PC may be discharged through the exposed pores S, thereby causing wafer defects and a reduction in production yield.

However, the part 100 with the corrosion-resistant layer 110 according to the first embodiment of the present invention may have a structure in which no voids exist therein. This may be realized by the pore corrosion-resistant layer 110b fully filling the pores S including the inside spaces thereof.

Specifically, since the part 100 with the corrosion-resistant layer 110 according to the first embodiment of the present invention includes the corrosion-resistant layer 110 formed by repeatedly performing the monoatomic layer generation cycle, the corrosion-resistant layer 110 may be formed even in fine-size pores S.

Specifically, the corrosion-resistant layer 110 may be formed by generating the plurality of monoatomic layers M that fills the entire pores S including the macropores S, the mesopores S, and the nanopores S. In the case of the part 100 with the corrosion-resistant layer 110 according to the first embodiment of the present, since the corrosion-resistant layer 110 is formed through the monoatomic layer generation cycle, the corrosion-resistant layer 110 may be disposed in the entire pores S formed in the depth direction of the porous ceramic body PC regardless of the pore size of the pores S existing near the surface of the porous ceramic body PC.

Therefore, as illustrated in FIGS. 3A and 3B, in the case of the part 100 with the corrosion-resistant layer 110 according to the first embodiment of the present invention, the corrosion-resistant layer 110 may be formed to fill the entire pores S including the nanopores S having the smallest width, thereby sealing the entire pores S.

In addition, the corrosion-resistant layer 110 may be formed to fill the entire pores S including the mesopores S having an intermediate width between the macropores S and the nanopores S, thereby sealing the entire pores S.

The part 100 with the corrosion-resistant layer 110 according to the first embodiment of the present invention may have a structure in which the corrosion-resistant layer 110 is disposed in the voids, i.e., the pores S, existing in the part 100 regardless of the pore size, as well as on the surface of the part 100. With this structure of the part 100 with the corrosion-resistant layer 110 according to the first embodiment of the present invention, even if the surface corrosion-resistant layer 110a is corroded, no exposed pores S may exist. Therefore, in the case of the part 100 with the corrosion-resistant layer 110 according to the first embodiment of the present invention, even if the surface corrosion-resistant layer 110a is corroded, the surface of the pore corrosion-resistant layer 110b filling the entire pores S may be exposed, so that the pores S may remain filled with the pore corrosion-resistant layer 110b and may not be exposed to the outside.

The part 100 with the corrosion-resistant layer 110 according to the first embodiment of the present invention may include the surface corrosion-resistant layer 100a formed on the surfaces of the grains G and the pore corrosion-resistant layer 110b filling the inside spaces of the pores S.

In the case of the part 100 with the corrosion-resistant layer 110 according to the first embodiment of the present invention, since the pore corrosion-resistant layer 110b fills the pores S of the porous ceramic body PC, the surface of the porous ceramic body PC may be completely sealed by the pore corrosion-resistant layer 110b even if the surface corrosion-resistant layer 110a is corroded and becomes thinner.

As a result, internal moisture and foreign substances existing inside the porous ceramic body PC may be prevented from being discharged through the exposed pores S. When provided in deposition equipment, the part 100 with the corrosion-resistant layer 110 according to the first embodiment of the present invention may minimize wafer defects and a deterioration in manufacturing quality, thereby improving the production yield of semiconductor devices. In addition, since the corrosion-resistant layer 110 has a thickness in a range of from several nm to several pm, the influence of the thickness on the thermal properties (thermal conductivity or thermal capacity) of the porous ceramic body PC may be minimized.

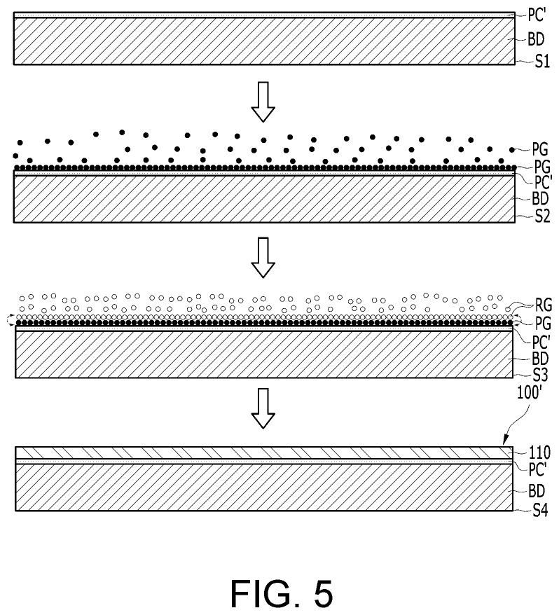

FIG. 5 is a view illustrating a process of manufacturing a modified example of a part 100′ with a corrosion-resistant layer 110 according to a second embodiment of the present invention.

As illustrated in FIG. 5, the part 100′ with a corrosion-resistant layer 110 according to the second embodiment of the present invention may include a body BD, a porous ceramic layer PC' formed on the body BD, and a corrosion-resistant layer 110 formed on a surface of the porous ceramic layer PC'.

The body BD may include a metal material. The metal material may include aluminum, titanium, tungsten, zinc, and alloys thereof. As illustrated in FIG. 5, the part 100′ with the corrosion-resistant layer 110 according to the second embodiment of the present invention may be manufactured by the following steps of: a preparation step (S1) of providing the body BD provided with the porous ceramic layer PC'; and a corrosion-resistant layer forming step (S4) of forming the corrosion-resistant layer 110 by repeating a monoatomic layer generation cycle including a precursor gas adsorption step (S2), an inert gas feeding step (not illustrated), a reactant gas adsorption and substitution step (S3), and an inert gas feeding step (not illustrated).

As illustrated in FIG. 5, the body BD provided with the porous ceramic layer PC' may be provided.

The porous ceramic layer PC' formed on at least one surface of the body BD may be formed by using, for example, a ceramic thermal spraying method. The porous ceramic layer PC' may be formed by thermal spraying of a thermal spray material.

The ceramic thermal spraying method is a technique for forming a film with a predetermined thickness on a metal or ceramic base material. A thermal spray material in powder form is fed into a plasma flow generated from an inert gas, heated instantaneously to a fully molten state, and accelerated toward the base material in the form of fine particles at a high deposition rate, followed by rapid cooling. Examples of the thermal spray material include powder, metal, non-metal, ceramic (mainly metal oxide, carbonate), cermet, and the like.

The porous ceramic layer PC' may have a porous structure. The porous structure may include a plurality of pores S.

The porous ceramic layer PC' may have the same configurations as those of the porous ceramic body PC of the part 100 with the corrosion-resistant layer 110 according to the first embodiment of the present invention, and may have a porous structure with the plurality of pores S. Accordingly, a detailed description of the configurations and structure of the porous ceramic layer PC' will be omitted.

The porous ceramic layer PC' may be formed on the surface of the body BD, thereby primarily imparting corrosion resistance to the body BD.

Then, the monoatomic layer generation cycle including the precursor gas adsorption step (S2), the inert gas feeding step (not illustrated), the reactant gas adsorption and substitution step (S3), and the inert gas feeding step (not illustrated) may be repeatedly performed. Thus, the corrosion-resistant layer 110 may be formed on the surface of the porous ceramic layer PC'.

The part 100′ with the corrosion-resistant layer 110 according to the second embodiment of the present invention may have a structure in which the corrosion-resistant layer 110 fills the pores S existing in the porous ceramic layer PC' as result of repeating monoatomic layer generation cycle.

The monoatomic layer generation cycle may allow a precursor gas PG and a reactant gas RG to penetrate into the pores S to form a plurality of monoatomic layers M on the entire inner surfaces of the pores S. This may realize a structure in which the corrosion-resistant layer 110 fully fills the inside spaces of the pores S of the porous ceramic layer PC'.

In the case of the part 100′ with the corrosion-resistant layer 110 according to the second embodiment of the present invention, the corrosion-resistant layer 110 formed on the surface of the porous ceramic layer PC' may secondarily impart corrosion resistance to the porous ceramic layer PC'. Since the corrosion-resistant layer 110 is formed on the surface of the porous ceramic layer PC', a corrosion prevention layer with a relatively large thickness may be formed on the surface of the body BD. As a result, the body BD may have high corrosion resistance. In this case, the porous ceramic layer PC' may be formed on the surface of the body BD to have a thin thickness, and the corrosion-resistant layer 110 may be formed on the surface of the porous ceramic layer PC' to have a predetermined thickness or a relatively thin thickness. This double-layered corrosion prevention structure is advantageous in minimizing a delamination problem over a single-layered corrosion prevention structure in which a thick corrosion prevention layer is formed on the surface of the body BD at one time.

The corrosion-resistant layer 110 may increase the strength of the porous ceramic layer PC' by filling the pores S of the porous ceramic layer PC' and may impart corrosion resistance to the surface thereof.

As a result, even if the corrosion-resistant layer 110 becomes thinner as it is corroded, the porous ceramic layer PC' having corrosion resistance is exposed without exposing the body BD. Therefore, the part 100′ with the corrosion-resistant layer 110 according to the second embodiment of the present invention may have high corrosion resistance.

In addition, since the corrosion-resistant layer 110 is formed on the surface of the porous ceramic layer PC' while the pore corrosion-resistant layer 110b fully fills the inside spaces of the pores S of the porous ceramic layer PC', even if a pore corrosion-resistant layer 110b is corroded, the pores S of the porous ceramic layer PC' may remain filled with the pore corrosion-resistant layer 110b and may not be exposed to the outside. Therefore, internal moisture and foreign substances may be prevented from being discharged through the pores S. As a result, the wafer defect rate may be reduced, thereby improving the production yield of semiconductor devices.

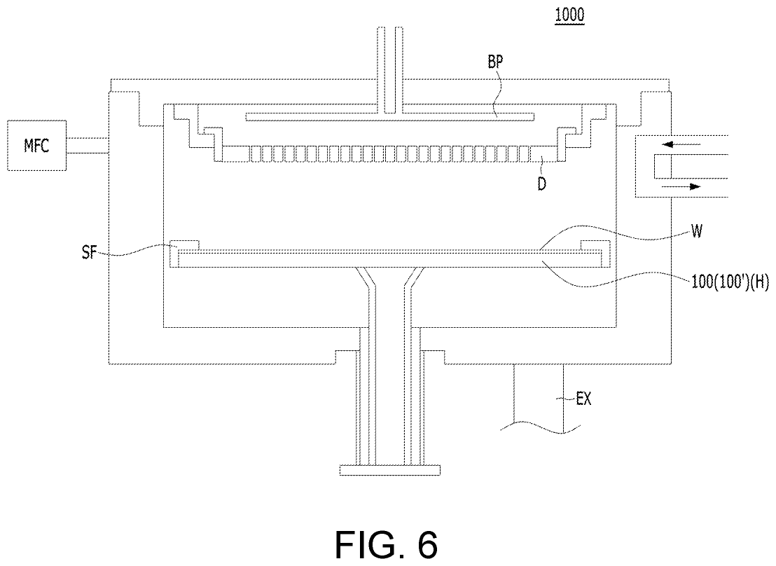

FIG. 6 is a schematic view illustrating a process chamber 1000 for a chemical vapor deposition process, the process chamber including at least one of the part 100 with the corrosion-resistant layer 110 according to the first embodiment of the present invention and the part 100′ with the corrosion-resistant layer 110 according to the second embodiment of the present invention.

The part 100 with the corrosion-resistant layer 110 according to the first embodiment of the present invention and the part 100′ with the corrosion-resistant layer 110 according to the second embodiment of the present invention may be provided as parts constituting the process chamber 1000 for the chemical vapor deposition process and may perform a deposition process.

The process chamber 1000 for the chemical vapor deposition process may include: a mass flow controller (MFC) provided outside the process chamber 1000; a ceramic heater H for semiconductors installed in the process chamber 1000 to support a wafer W; a backing plate BP disposed on an upper portion of the process chamber 1000; a diffuser D disposed under the backing plate BP to feed a process gas to the wafer W; a shadow frame SF disposed between the ceramic heater H for semiconductors and the diffuser D to cover the edge of the wafer W; a process gas exhaust part EX through which the process gas fed from a process gas feeding part (not illustrated) is exhausted; and a slit valve (not illustrated) installed in the process gas feeding part and the process gas exhaust part EX.

The part 100 with the corrosion-resistant layer 110 according to the first embodiment of the present invention and the part 100′ with the corrosion-resistant layer 110 according to the second embodiment of the present invention may be provided as, for example, the ceramic heater H for semiconductors constituting the process chamber 1000 for the chemical vapor deposition process.

The process chamber 1000 for the chemical vapor deposition process may perform the chemical vapor deposition process as follows: the process gas fed from the process gas feeding part is introduced into the backing plate BP, and then sprayed onto the wafer W through through-holes of the diffuser D. The process gas is a gas in a plasma state and has strong corrosive and erosive properties.

As the process chamber 1000 for the chemical vapor deposition process repeatedly performs the deposition or cleaning process, the parts constituting the process chamber 1000 for the chemical vapor deposition process come into contact with the process gas.

The part 100 with the corrosion-resistant layer 110 according to the first embodiment of the present invention and the part 100′ with the corrosion-resistant layer 110 according to the second embodiment of the present invention may have improved corrosion resistance imparted by the corrosion-resistant layers 110 formed on the surfaces of the porous ceramic body PC and the porous ceramic layer PC'.

In addition, in the case of the part 100 with the corrosion-resistant layer 110 according to the first embodiment of the present invention and the part 100′ with the corrosion-resistant layer 110 according to the second embodiment of the present invention, even if the corrosion-resistant layers 110 are corroded and become thinner when exposed to the process gas after long-term use, the pores S of the porous ceramic body PC and the porous ceramic layer PC' may be prevented from being exposed to the outside. This may be realized by the pore corrosion-resistant layers 110b filling the pores S. In the case of the part 100 with the corrosion-resistant layer 110 according to the first embodiment of the present invention, the surface corrosion-resistant layer 110a may be formed on the surface of the porous ceramic body PC and the pore corrosion-resistant layer 110 may fill the pores S, thereby forming the corrosion-resistant layer 110. Also, in the case of the part 100′ with the corrosion-resistant layer 110 according to the second embodiment of the present invention, the surface corrosion-resistant layer 110a may be formed on the surface of the porous ceramic layer PC' and the pore corrosion-resistant layer 110 may fill the pores S, thereby forming the corrosion-resistant layer 110. With the provision of the surface corrosion-resistant layers 110a having a predetermined thickness, surface corrosion resistance may be improved. In addition, with the provision of the pore corrosion-resistant layers 110b filling the pores S, even if the surface corrosion-resistant layers 110a are corroded and become thinner thin when exposed to the process gas after long-term use, the pores S may remain filled with the pore corrosion-resistant layers 110b and may not be exposed to the outside.

The pores S may act as a significant source of causing contamination and defects on the wafer W by allowing internal moisture and process foreign substances to be discharged therethrough to the outside. In the case of the part 100 with the corrosion-resistant layer 110 according to the first embodiment of the present invention and the part 100′ with the corrosion-resistant layer 110 according to the second embodiment of the present invention, the surface corrosion-resistant layers 110a and the pore corrosion-resistant layers 110b filling the pores S may be formed during the process of forming the corrosion-resistant layers 100. Since the pore corrosion-resistant layers 110b fill the pores S, this may realize a structure in which no pores S exist. In the case of the part 100 with the corrosion-resistant layer 110 according to the first embodiment of the present invention and the part 100′ with the corrosion-resistant layer 110 according to the second embodiment of the present invention, even if the surface corrosion-resistant layers 110a are corroded and become thinner, no exposed pores S may exist because the pores S remain filled with the pore corrosion-resistant layers 110b. Therefore, internal moisture and foreign substances may be prevented from being discharged through the pores S. As a result, contamination and defects on the wafer W may be reduced, thereby improving the production yield of semiconductor devices.

Although the exemplary embodiments of the present invention have been described for illustrative purposes, those skilled in the art will appreciate that various modifications, additions, and substitutions are possible, without departing from the scope and spirit of the invention as disclosed in the accompanying claims.

What is claimed is:

1. A part with a corrosion-resistant layer, the part comprising:
a porous ceramic body with a plurality of pores; and
the corrosion-resistant layer formed on a surface of the porous ceramic body,
wherein the corrosion-resistant layer is formed to fill the pores of the porous ceramic body, thereby sealing the pores.

2. The part with the corrosion-resistant layer of claim 1, wherein the porous ceramic body comprises at least one of alumina (Al₂O₃), aluminum nitride (AlN), silicon carbide (SiC), yttria (Y₂O₃), boron nitride (BN), zirconia (ZrO₂), and silicon nitride (Si₃N₄).

3. The part with the corrosion-resistant layer of claim 1, wherein the corrosion-resistant layer comprises at least one of an aluminum oxide layer, an yttrium oxide layer, a hafnium oxide layer, a silicon oxide layer, an erbium oxide layer, a zirconium oxide layer, a fluoride layer, a transition metal layer, a titanium nitride layer, a tantalum nitride layer, and a zirconium nitride layer.

4. The part with the corrosion-resistant layer of claim 1, wherein the corrosion-resistant layer comprises:
a surface corrosion-resistant layer formed on the surface of the porous ceramic body; and
a pore corrosion-resistant layer formed inside the pores of the porous ceramic body,
wherein a length of the pore corrosion-resistant layer in a depth direction of the porous ceramic body is larger than a thickness of the surface corrosion-resistant layer in at least a partial area.

5. The part with the corrosion-resistant layer of claim 1, wherein the pores comprise macropores, mesopores, and nanopores that have different pore sizes, respectively, and
the corrosion-resistant layer seals the pores by filling the nanopores.

6. The part with the corrosion-resistant layer of claim 1, wherein the pores comprise macropores, mesopores, and nanopores that have different pore sizes, respectively, and
the corrosion-resistant layer seals the pores by filling the mesopores.

7. The part with the corrosion-resistant layer of claim 1, wherein the corrosion-resistant layer is formed by alternately feeding a precursor gas, which is at least one of aluminum, silicon, hafnium, zirconium, yttrium, erbium, titanium, and tantalum, and a reactant gas capable of forming the corrosion-resistant layer.

8. A part with a corrosion-resistant layer, the part comprising:
a body;
a porous ceramic layer formed on the body and provided with a plurality of pores; and
the corrosion-resistant layer formed on a surface of the porous ceramic layer,
wherein the corrosion-resistant layer fills the pores of the porous ceramic layer, thereby sealing the pores.

9. The part with the corrosion-resistant layer of claim 8, wherein the porous ceramic layer is formed by thermal spraying of a thermal spray material.

10. The part with the corrosion-resistant layer of claim 8, wherein the porous ceramic layer comprises at least one of alumina (Al₂O₃), aluminum nitride (AlN), silicon carbide (SiC), yttria (Y₂O₃), boron nitride (BN), zirconia (ZrO₂), and silicon nitride (Si₃N₄).

11. The part with the corrosion-resistant layer of claim 8, wherein the corrosion-resistant layer comprises:
a surface corrosion-resistant layer formed on the surface of the porous ceramic layer; and
a pore corrosion-resistant layer formed inside the pores of the porous ceramic layer,
wherein a length of the pore corrosion-resistant layer in a depth direction of the porous ceramic layer is larger than a thickness of the surface corrosion-resistant layer in at least a partial area.

12. The part with the corrosion-resistant layer of claim 8, wherein the pores comprise macropores, mesopores, and nanopores that have different pore sizes, respectively, and
the corrosion-resistant layer seals the pores by filling the nanopores.

13. The part with the corrosion-resistant layer of claim 8, wherein the pores comprise macropores, mesopores, and nanopores that have different pore sizes, respectively, and
the corrosion-resistant layer seals the pores by filling the mesopores.

14. The part with the corrosion-resistant layer of claim 8, wherein the corrosion-resistant layer is formed by alternately feeding a precursor gas, which is at least one of aluminum, silicon, hafnium, zirconium, yttrium, erbium, titanium, and tantalum, and a reactant gas capable of forming the corrosion-resistant layer.
